(19) United States
(12) Patent Application Publication
(10) Pub. No.: US 2025/0250666 A1
(43) Pub. Date: Aug. 7, 2025

(54) LATERAL GAP FILL

(71) Applicant: Lam Research Corporation, Fremont, CA (US)

(72) Inventors: Daniel Christopher MESSINA, Tigard, OR (US); Douglas Walter AGNEW, Portland, OR (US); Jennifer Leigh PETRAGLIA, Lake Oswego, OR (US); Mary Waddington GRUMBLES, Portland, OR (US)

(21) Appl. No.: 18/856,864

(22) PCT Filed: Apr. 19, 2023
(86) PCT No.: PCT/US2023/019167

§ 371 Date: Oct. 14, 2024

Related U.S. Application Data
(60) Provisional application No. 63/377,684, filed on Sep. 29, 2022.
(60) Provisional application No. 63/363,269, filed on Apr. 20, 2022.

(51) Int. Cl. C23C 16/04; C23C 16/02; C23C 16/32; C23C 16/34; C23C 16/40; C23C 16/455

(52) U.S. Cl. CPC C23C 16/045; C23C 16/0227; C23C 16/042; C23C 16/32; C23C 16/34; C23C 16/40; C23C 16/45536

(57) ABSTRACT

Inhibition of dielectric film growth is described. The inhibition may be used during atomic layer deposition (ALD) processes of dielectric material in gaps to facilitate bottom-up (or inside-out) gap fill. One or more inhibition operations are performed during gap fill. The inhibition operation modifies the surface of the gap in a manner that inhibits growth in subsequent ALD cycles.

### RELATED APPLICATION(S)

A PCT Request Form is filed concurrently with this specification as part of the present application. Each application that the present application claims benefit of or priority to as identified in the concurrently filed PCT Request Form is incorporated by reference herein in its entirety and for all purposes

### BACKGROUND

Many semiconductor device fabrication processes involve formation of films including silicon-containing films such as silicon oxide or silicon nitride. Depositing a high-quality film can be particularly challenging when depositing films in gaps. Challenges can include the formation of voids and/or seams in the films.

The background description provided herein is for the purposes of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

### SUMMARY

Aspects of the disclosure relate to atomic layer deposition (ALD) of dielectric material in gaps that facilitates void-free bottom-up or inside-out gap fill. One or more inhibition operations are performed during gap fill. The inhibition operation modifies the surface of the gap in a manner that inhibits growth in subsequent ALD cycles.

One aspect of the disclosure relates to a method for filling a feature of a structure on a substrate in a chamber, the method including: performing one or more cycles of:
(a) providing a halogen-containing gas to the chamber under non-plasma conditions to inhibit deposition on at least part of the feature;
(b) performing one or more atomic layer deposition cycles to deposit a dielectric material in the feature.

In some embodiments, the dielectric material is an oxide, a nitride, or a carbide. In some embodiments, the method further includes before performing one or more cycles of (a) and (b), depositing a liner layer in the feature by atomic layer deposition.

In some embodiments, operation (a) results in a self-limiting etch.

In some embodiments, operation (a) results in a halogen-terminated surface.

In some embodiments, the method further includes providing water or one or more reactants that can form water to the chamber. In some embodiments, operation (b) includes providing a halogen-containing gas, hydrogen (H₂), and oxygen (O₂) to the chamber.

In some embodiments, the structure includes a vertically-oriented feature, the vertically-oriented feature having sidewalls, a plurality of openings in the sidewalls leading to a plurality of laterally-oriented features fluidically accessible through the plurality of openings, and wherein the feature is one of the laterally-oriented features.

In some embodiments, the method further includes performing one or more cycles of:
(c) providing a halogen-containing gas or a halogen-free gas to the chamber under plasma conditions to inhibit deposition on at least part of the feature;
(d) performing one or more atomic layer deposition cycles to deposit a dielectric material in the feature.

According to various embodiments, the cycles of (c) and (d) may be performed before, after, or interspersed with the cycles of (a) and (d).

Another aspect of the disclosure relates to an apparatus including: a chamber for housing a substrate; a gas inlet to inlet gases to the chamber; and a controller including instructions for:
(a) providing a halogen-containing gas to the chamber under non-plasma conditions to inhibit deposition on at least part of the feature;
(b) performing one or more atomic layer deposition cycles to deposit a dielectric material in the feature.

Another aspect of the disclosure relates to a method for filling a feature of a structure on a substrate in a chamber, including performing one or more inhibition-deposition cycles of:
(a) providing a plasma generated from a nitrogen-containing halogen-free gas to the chamber to inhibit deposition on at least part of the feature, wherein the chamber pressure is at least 5 Torr during (a); and
(b) performing one or more atomic layer deposition cycles to deposit a dielectric material in the feature.

In some embodiments, the dielectric material is an oxide, a nitride, or a carbide. In some embodiments, the method further includes, before performing the one or more inhibition-deposition cycles of (a) and (b), depositing a liner layer in the feature by atomic layer deposition.

In some embodiments, the structure includes a vertically-oriented feature, the vertically-oriented feature having openings leading to a plurality of laterally-oriented features fluidically accessible through the plurality of openings, and wherein the feature is one of the laterally-oriented features. In some embodiments, the vertically-oriented feature has a depth of at least 1 micron. In some embodiments, the vertically-oriented feature has a depth of at least 2 microns.

In some embodiments, (b) includes one or more plasma-enhanced atomic layer deposition cycles. In some such embodiments, the plasma power during (b) is higher than during (a) In some embodiments, (b) includes one or more thermal atomic layer deposition cycles.

In some embodiments, (b) is performed only once per inhibition-deposition cycle. In some embodiments, a duration of (a) is at least 10 seconds per inhibition-deposition cycle. In some embodiments, a duration of (a) is at least 20 seconds per inhibition-deposition cycle. In some embodiments, a duration of (a) is at least 30 seconds per inhibition-deposition cycle. In some embodiments, the plasma in (a) is generated from N₂ gas. In some such embodiments, the plasma in (a) is generated from a mixture of the N₂ gas with hydrogen gas (H₂). In some embodiments, the plasma in (a) is generated from NH₃ gas. In some embodiments, the plasma in (a) densifies dielectric film in the laterally-oriented features.

Another aspect of the disclosure relates to a method including providing a substrate having a structure to a process chamber, the structure including a vertically-oriented feature, a plurality of openings in the vertically-oriented feature leading to a plurality of laterally-oriented features fluidically accessible through the plurality of openings, wherein the vertically-oriented feature is at least 1 micron deep; and performing multiple cycles of:
(a) exposing the substrate to a plasma generated from N₂ to selectively inhibit a portion of the laterally-oriented features, wherein the pressure of the process chamber during (a) is at least about 5 Torr, and wherein a duration of (a) is at least about 10 seconds; and
(b) after (a), depositing dielectric material in the laterally-oriented features by a plasma-enhanced atomic layer deposition process, wherein the plasma power in (a) is less than that in (b).

In some embodiments, the plasma in (a) densifies dielectric film in the laterally-oriented features.

Another aspect of the disclosure relates to a method including providing a substrate having a structure to a process chamber, the structure including a vertically-oriented feature, a plurality of openings in the vertically-oriented feature leading to a plurality of laterally-oriented features fluidically accessible through the plurality of openings, wherein the vertically-oriented feature is at least 1 micron deep; and performing multiple cycles of:
(a) exposing the substrate to an inhibition plasma to selectively inhibit a portion of the laterally-oriented features; and
(b) after (a), depositing dielectric material in the laterally-oriented features by an atomic layer deposition process.

In some embodiments, the inhibition plasma is halogen-free. In some embodiments, the inhibition plasma is halogen-containing. In some embodiments, the inhibition plasma is generated in a capacitively-coupled plasma generator. In some embodiments, the inhibition plasma is generated in an inductively-coupled plasma generator. In some embodiments, the inhibition plasma has a high radical density. In some embodiments, a pressure of the process chamber during (a) is at least about 1 Torr

Another aspect of the disclosure relates an apparatus including: a chamber for housing a substrate; a plasma generator for generating a plasma in the chamber; a gas inlet to inlet gases to the chamber; and a controller including instructions for:
(a) providing a plasma generated from a nitrogen-containing halogen-free gas to the chamber to inhibit deposition on at least part of the feature, wherein the chamber pressure is at least 5 Torr during (a); and
(b) performing one or more atomic layer deposition cycles to deposit a dielectric material in the feature.

These and other features of the disclosed embodiments will be described in detail below with reference to the associated drawings.

### BRIEF DESCRIPTION OF THE DRAWINGS

FIG. 1 shows an illustration of an example of a structure that may be filled with dielectric material according to various embodiments.

FIG. 2 shows an illustration of an example of a structure that may be filled with dielectric material according to various embodiments.

FIG. 3A is a flow diagram showing an example of a method for filling features according to various embodiments.

FIG. 3B shows an example of process sequence that may be used in accordance with the disclosed embodiments.

FIG. 4 is a graph showing thickness as dielectric film as a function of duration of a thermal inhibition process.

FIG. 5 is a graph showing thickness after thermal inhibition and deposition.

FIG. 6 is a flow diagram showing an example of a method for filling features according to various embodiments.

FIG. 7 shows an example of process sequence that may be used in accordance with the disclosed embodiments.

FIG. 8 is a flow diagram showing an example of a method for atomic layer deposition (ALD) according to various embodiments.

FIG. 9 is a schematic diagram of an example process station for performing disclosed embodiments.

FIGS. 10-12 are a schematic diagrams example process tools for performing disclosed embodiments.

### DETAILED DESCRIPTION

In the following description, numerous specific details are set forth to provide a thorough understanding of the presented embodiments. The disclosed embodiments may be practiced without some or all these specific details. In other instances, well-known process operations have not been described in detail to not unnecessarily obscure the disclosed embodiments. While the disclosed embodiments will be described in conjunction with the specific embodiments, it will be understood that it is not intended to limit the disclosed embodiments.

Semiconductor fabrication processes often include dielectric gap fill using chemical vapor deposition (CVD) and/or atomic layer deposition (ALD) methods to fill features. Described herein are methods of filling features with dielectric material including but not limited to silicon-containing films such as silicon oxide, and related systems and apparatuses. The methods described herein can be used to fill features formed in a substrate. Such features may be referred to as gaps, recessed features, negative features, unfilled features, or simply features. Filling such features may be referred to as gap fill. Features formed in a substrate can be characterized by one or more of narrow and/or re-entrant openings, constrictions within the feature, and high aspect ratios. In some implementations, a feature may have an aspect ratio of at least about 2:1, at least about 4:1, at least about 6:1, at least about 20:1, at least about 100:1, or greater. The substrate may be a silicon wafer, e.g., a 200-mm wafer, a 300-mm wafer, or a 450-mm wafer, including wafers having one or more layers of material such as dielectric, conducting, or semi-conducting material deposited thereon.

One aspect of the disclosure relates to atomic layer deposition (ALD) of dielectric material in gaps that facilitates void-free bottom-up (or inside-out) gap fill. One or more inhibition operations are performed during gap fill. The inhibition operation modifies the surface of the gap in a manner that inhibits growth in subsequent ALD cycles.

Examples of structures to be filled include 3D NAND structures, dynamic random access memory (DRAM) structures, and shallow trench isolation (STI) structures. The structures include gaps with the sidewalls of the gaps formed by a material susceptible to etch. In one example, 3D NAND structure includes oxide-nitride-oxide-nitride (ONON) stacks covered with a poly Si layer. Other examples of sidewall materials include oxides, metals, and semiconducting materials.

According to various embodiments, the methods may be implemented to fill vertically-oriented features and/or laterally-oriented features. For example, in vertical DRAM (VDRAM) structures, ALD may be used to fill laterally-oriented trenches.

While the description herein chiefly describes filling a feature with dielectric material in a void-free manner, in some embodiments, the methods may be implemented to form air gaps in features. In such embodiments, deposition on most or all of a feature may be inhibited to facilitate pinch off at the top of a gap and the formation of a void or air gap within the feature. In this manner, capacitance may be reduced.

The features described herein generally having an opening and sidewalls extending from the opening further into the feature. Vertically-oriented features have an axis extending from the opening and between the sidewalls, the axis oriented generally orthogonal to the plane of the substrate. Laterally-oriented features have an axis extending from the opening and between the sidewalls, the axis oriented generally parallel to the plane of the substrate.

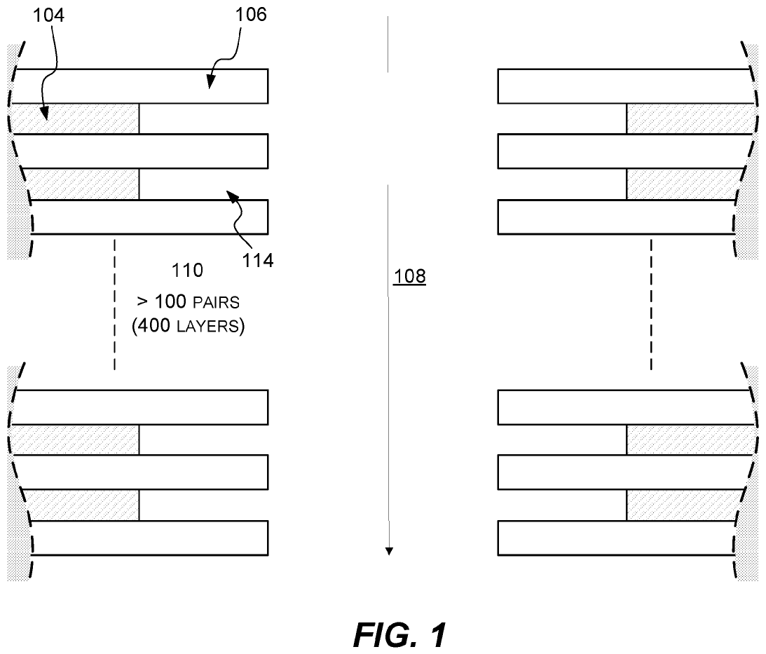

FIG. 1 shows an example of a portion of a VDRAM structure that may be filled using the methods described herein. The structure includes multiple pairs, each pair including a layer 104 and a layer 106. Examples of materials for layer 104 include silicon germanium (SiGe), silicon nitride (SiN), and silicon dioxide (SiO₂). Examples of materials for layer 106 include silicon (Si), silicon dioxide (SiO₂), and silicon nitride (SiN). Laterally-oriented features 114 are formed by etching and are to be filled with dielectric material. The laterally-oriented features 114 are formed in a vertically-oriented hole 108, which also may be referred to as a vertically-oriented feature. Examples of depths of vertically-oriented features include at least 0.1 microns, at least 0.5 microns, at least 1 micron, at least 2 microns, at least 4 microns, and at least 5 microns. A VDRAM structure may have anywhere from a few pairs to hundreds of pairs. Example aspect ratios of the vertically-oriented trench are at least 30:1, at least 50:1, at least 100:1 and higher. Example opening widths of the laterally-oriented features are 5-20 nm. Example aspect ratios are of the laterally-oriented features are at least 10:1, at least 20:1, or at least 25:1.

The laterally-oriented features 114 are fluidically accessible through openings in the vertically-oriented hole 108. That is, a gas can reach the laterally-oriented features if not closed off. Void-free fill by ALD relies on migration of sufficient quantities of deposition precursor down through the vertically-oriented hole 108, through openings of the laterally-oriented features 114, and into the furthest reaches of the laterally-oriented features, prior to the accumulated deposition of dielectric material that can pinch-off of the openings and preventing further precursor migration into laterally-oriented features 114.

Structures as shown in FIG. 1 are challenging to fill with ALD processes. While ALD can result in conformal growth on a structure, conformal growth from the sidewalls can result in a seam down the middle of each feature. Further, it can be difficult to achieve top-to-bottom uniformity such that the laterally-oriented features 114 near the bottom of the structure are filled to the same extent as the laterally-oriented features 114 near the top of the structure.

Lateral gap fill presents challenges that are not present with filling with vertically-oriented features. For example, an a plasma inhibition operation may be used during ALD to fill an vertically-oriented feature. An inhibitor plasma creates a passivated surface and increases a nucleation barrier of the deposited ALD film. When the inhibitor plasma interacts with material in the feature, the material at the bottom of the feature receives less plasma treatment than material located closer to a top portion of the feature or in field because of geometrical shadowing effects. As a result, deposition at the top of the feature is selectively inhibited and deposition in lower portions of the feature proceeds with less inhibition or without being inhibited. Bottom-up fill is enhanced, which creates a more favorable sloped profile that mitigates the seam effect and prevents void formation.

However, if a similar process is used to fill a VDRAM structure as shown in FIG. 1, however, the laterally-oriented features at the bottom of the vertically-oriented thole 108 may be more inhibited than those at the top. This would result in non-uniform feature-to-feature fill. The methods described herein may be used for uniform top-to-bottom inhibition and uniform feature-to-feature fill.

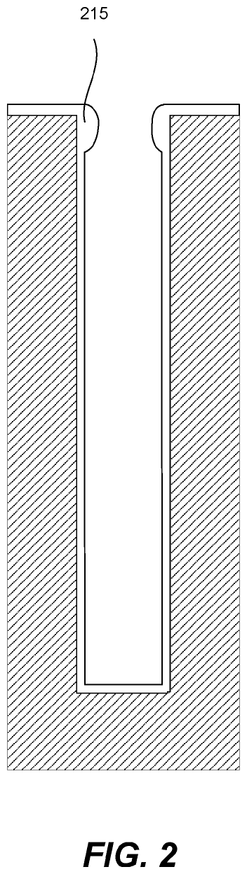

In addition to laterally-oriented features as in the example of FIG. 1, the gap fill processes may be used to fill other types of features in which fill is challenging. These include high aspect ratio features including vertically-oriented features having aspect ratios of 10:1 or greater. In some embodiments, a feature to be filled is a re-entrant feature. A re-entrant feature is a feature that narrows at some point from the bottom or interior of the feature to the opening. FIG. 2 shows an example of a re-entrant feature to be filled. The feature includes a cusp 215 that can make fill challenging.

Described herein are gap fill processes that includes thermal inhibition or plasma-based inhibition operations. A thermal inhibition operation is an operation that uses a non-plasma inhibition gas. No plasma is generated. A plasma-based inhibition process uses a process gas that includes plasma species, such as ions and/or radical species.

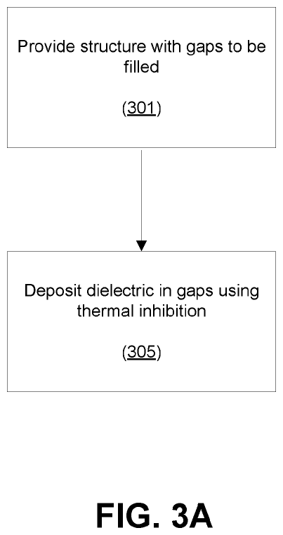

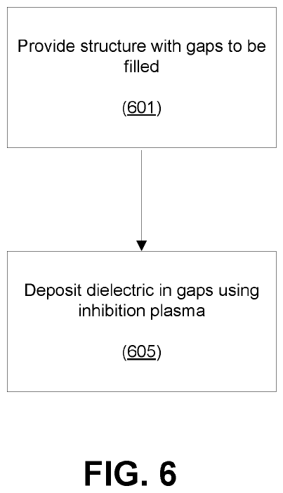

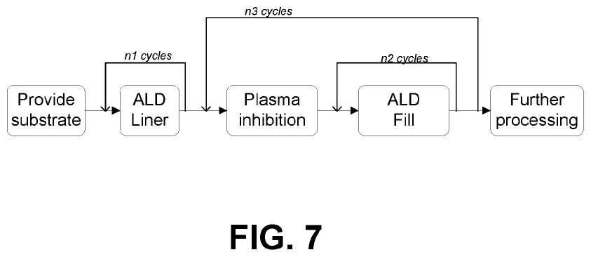

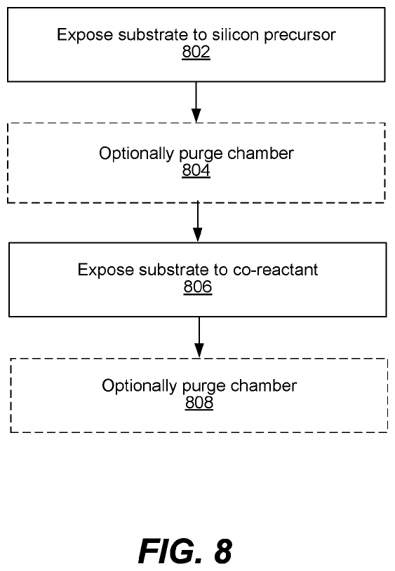

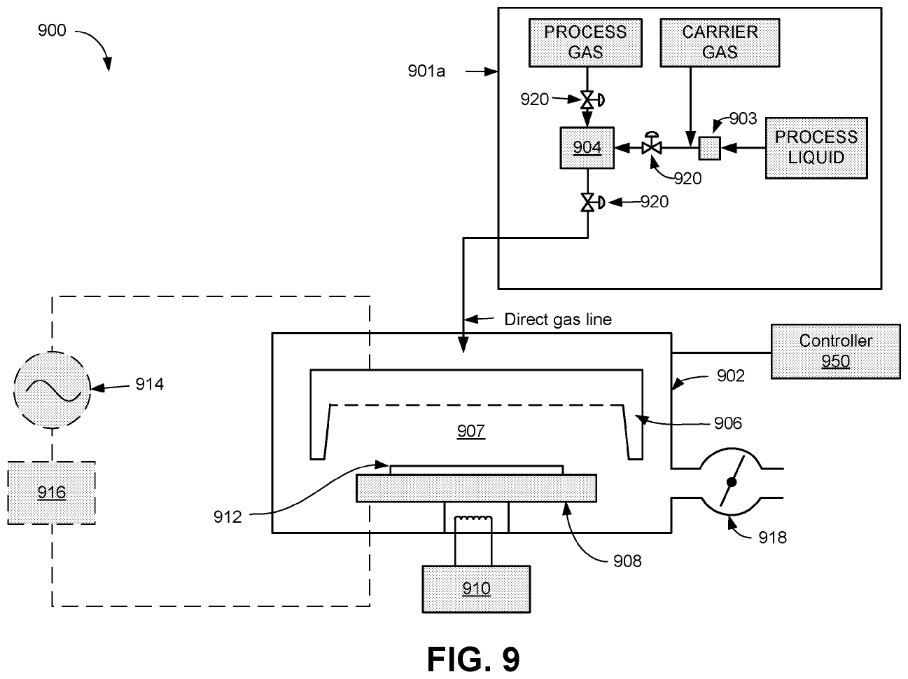

Thermal inhibition processes are described below with reference to FIGS. 3-5, with plasma-based inhibition processes described below with reference to FIGS. 6 and 7. Atomic layer deposition processes that may be used with the methods herein are described with reference to FIG. 8. Apparatus for implementing the methods described herein are described with reference to FIGS. 9-12.

FIG. 3A is a process flow diagram that illustrates a method of filling gaps with dielectric material. The method begins with providing a structure with one or more gaps to be filled in an operation 301. The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gap fill other substrates, such as glass, plastic, and the like, including in the fabrication of microelectromechanical (MEMS) devices.

Examples of structures include VDRAM structures, 3D NAND structures, and shallow trench isolation (STI) structures. The structures include gaps with the sidewalls of the gaps formed by a material susceptible to etch. In some embodiments, structures may include lateral structures that extend horizontally from a common vertical trench. Examples of sidewall materials include nitrides, oxides, metals, and semiconducting materials. The methods described herein are not limited to a particular class of sidewall material and may be used to inhibit any susceptible material.

Dielectric material is deposited in the gaps using thermal inhibition during fill in an operation 305. As discussed further below, this can involve cycles of atomic layer deposition (ALD) of the dielectric film followed by exposure to an inhibition gas.

Thermal inhibition involves a non-plasma exposure to a halogen-containing inhibition gas. The halogen-containing inhibition gas may be a fluorine (F)-containing gas, a chlorine (Cl)-containing gas, a bromine (Br)-containing gas, an iodine (I)-containing gas, or any combination thereof. Non-plasma conditions refer to conditions in the absence of a plasma. In some embodiments, one or more additional gases are introduced to the chamber to be present in the chamber with the halogen-containing gas. The one or more additional gases may be flowed into the chamber with the halogen-containing gas or introduced separately.

The thermal inhibition operation may be performed on previously formed dielectric material. In some embodiments, the thermal inhibition results in a surface that is at least partially halogen terminated.

In some embodiments, inhibiting species are produced within a reactor from a halogen-containing gas with one or more additional gases. For example, nitrogen trifluoride (NF3) and water (H₂O) may be reacted to produce hydrogen fluoride (HF), which can then react with the deposited film to produce a fluorine-terminated film. In some embodiments, hydrogen (H₂) and oxygen (O₂) are introduced to the chamber to form water. Other water sources may be used.

In some embodiments, HF or other inhibiting species that reacts with the deposited film is introduced by itself or only an inert carrier or background gas.

In some embodiments, the thermal inhibition operation results in a self-limiting etch of previously formed dielectric material. For example, a few Angstroms of material may be etched, with the etched surface being halogen-terminated. This inhibits subsequent deposition. Further discussion of halogen-containing gases and process conditions during the thermal inhibition are provided further below.

FIG. 3B shows an example of a process sequence that may be used in accordance with certain embodiments. In the example process sequence of FIG. 3B, a substrate such as a semiconductor wafer is provided for gap fill. It may be provided to a deposition chamber having undergone previous processing and/or be maintained in a deposition chamber. At this stage, the substrate includes one or more features to be filled with dielectric material. For example, a substrate having a structure with laterally-oriented features as shown in FIG. 1 or a substrate having a gap with an overhang as shown in FIG. 2 may be provided.

Then, n1 cycles of ALD deposition are performed, with n1 being an integer of at least one (1). ALD is a technique that sequentially deposits thin layers of material. ALD processes use surface-mediated deposition reactions to deposit films on a layer-by-layer basis in cycles. The concept of an ALD “cycle” is relevant to the discussion of various embodiments herein. Generally, a cycle is the minimum set of operations used to perform a surface deposition reaction one time. The result of one cycle is the production of at least a partial silicon-containing film layer on a substrate surface. Typically, an ALD cycle includes operations to deliver and adsorb at least one reactant to the substrate surface, and then react the adsorbed reactant with one or more reactants to form the partial layer of film. The cycle may include certain ancillary operations such as sweeping one of the reactants or byproducts and/or treating the partial film as deposited. Generally, a cycle contains one instance of a unique sequence of operations. As an example, an ALD cycle may include the following operations: (i) delivery/adsorption of a precursor, (ii) purging of the precursor from the chamber, (iii) delivery of a second reactant (also referred to as a co-reactant) and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In a plasma-enhanced ALD (PEALD) process, a plasma may be ignited during or after the delivery of the second reactant in (iii). Thermal ALD processes are non-plasma processes. In the examples described herein with respect to FIG. 3B, the ALD process is generally a thermal ALD process.

In one example of an ALD process, a substrate surface that includes a population of surface-active sites is exposed to a gas phase distribution of a first precursor, such as a silicon-containing precursor, in a dose provided to a chamber housing the substrate. Molecules of this first precursor are adsorbed onto the substrate surface, including chemisorbed species and/or physisorbed molecules of the first precursor. When a compound is adsorbed onto the substrate surface as described herein, the adsorbed layer may include the compound as well as derivatives of the compound. For example, an adsorbed layer of a silicon-containing precursor may include the silicon-containing precursor as well as derivatives of the silicon-containing precursor. After a first precursor dose, the chamber is then evacuated to remove most or all of first precursor remaining in gas phase so that mostly or only the adsorbed species remain. In some implementations, the chamber may not be fully evacuated. For example, the reactor may be evacuated such that the partial pressure of the first precursor in gas phase is sufficiently low to mitigate a reaction. A second reactant, such as an oxygen-containing gas or nitrogen-containing gas, is introduced to the chamber so that some of these molecules react with the first precursor adsorbed on the surface. In some processes, the second reactant reacts immediately with the adsorbed first precursor. In other embodiments, the second reactant reacts only if a source of activation such as plasma is applied temporally. The chamber may then be evacuated again to remove unbound second reactant molecules. As described above, in some embodiments the chamber may not be completely evacuated. Additional ALD cycles may be used to build film thickness.

In the example of FIG. 3B, the n1 cycles are sufficient to deposit a thin liner layer within the one or more features to be filled with dielectric material. The layer is generally conformal to the structure.

While the n1 cycles of ALD are generally thermal ALD cycles, there may be instances in which PEALD is appropriate. Further, the method may be used with other sources of activation such as exposure to UV light.

As indicated above, in some embodiments, a silicon-containing film is deposited by ALD. Examples of silicon-containing reactants that may be used in the ALD methods are provided further below. The methods may also be used to form other dielectric films including oxides such as gallium oxide, vanadium dioxide, hafnium oxide, zinc oxide, zirconium oxide, aluminum oxide, lithium (II) oxide, beryllium oxide, boron (III) oxide, magnesium oxide, titanium (III) oxide, iron (III) oxide, cobalt (II) oxide, and germanium (IV) oxide and nitrides such as gallium nitride, aluminum nitride, lithium nitride, and boron nitride Metals such as molybdenum, iron, cobalt, and germanium, and compounds such as SiGe may be formed using these techniques. Example of reactants that may be used for these certain films are described below.

The second reactant (also referred to as a co-reactant) may vary depending on the film to be deposited. Silicon and other oxides may be deposited, for example, using oxygen (O₂) as second reactant. Other second reactants may be used including other oxidants to deposit oxides, nitrogen-containing reactants to deposit nitrides, carbon-containing reactants to deposit carbides, etc. Examples include O₂ and/or nitrous oxide (N₂O) to form a silicon oxide layer or silicon oxynitride layer, nitrogen (N₂) or ammonia (NH₃) to form a silicon nitride layer, methane (CH₄) to generate a silicon carbide layer etc. Appropriate mixtures of reactants may be used to form oxycarbides, oxycarbonitrides, oxynitrides, carbonitrides, etc.

After the n1 cycles are of ALD are performed to deposit a liner film, a thermal inhibition process is performed. As described above, the thermal inhibition process involves exposure to a halogen-containing gas.

The thermal inhibition process may involve a continuous flow of the halogen-containing gas, and other gases if present. In some embodiments, one or more of the gases flowed into the chamber may be pulsed. For example, a halogen-containing gas may be pulsed. If one or more additional gases is used, it may be flowed continuously and/or pulsed as well. Similarly, an additional gas such as hydrogen and/or oxygen may be pulsed.

Returning to FIG. 3B, after the thermal inhibition process is performed, n2 ALD cycles are performed to deposit dielectric material, including in the one or more features on the substrate to be filled. The reactants and deposited film in the ALD fill may be the same or different than used and formed in the ALD liner operation. The number of cycles, n2, is an integer of at least one and may be at least 2, at least 3, at least 4, at least 5, at least 6, at least 7, at least 8, at least 9,or at least 10. The number of cycles may depend on structure geometry. Fewer cycles (and thus more inhibition and suppression of growth rate) may be used for structures that are more challenging to fill due to re-entrancy, narrow openings, and/or high aspect ratios. The thermal inhibition and n2 ALD cycles may be repeated for n3 total cycles, with n3 an integer of at least one. (If any of n1, n2, or n3 is one, the cycle under consideration is not repeated). In some embodiments, the number n3 of total inhibition-fill cycles is sufficient to complete fill of one or more features. In some embodiments, a n2 of 2, 3, or 4 may be used. According to various embodiments, the number n2 may be constant throughout the process or may vary. For example, at the beginning of the fill process, the inhibition may be more frequent. As the features beginning from the bottom up or inside out, the fill may become less challenging, allowing less frequent inhibition.

After the n3 cycles of thermal inhibition-ALD fill are completed, further processing may be performed. This can include further ALD, PEALD, chemical vapor deposition (CVD), or plasma enhanced chemical vapor deposition (PECVD) of dielectric material, planarization, etching, etc.

In addition to laterally-oriented features as in the example of FIG. 1, the thermal inhibition may be used with other features in which plasma inhibition is challenging. These include high aspect ratio features including vertically-oriented features having aspect ratios of 10:1 or greater.

In some embodiments, the thermal inhibition may be used on re-entrant features as described with respect to FIG. 2. Because the thermal inhibition process is conformal, it can be used to inhibit deposition on the underside of the cusp 215, facilitating fill below. In some embodiments, thermal inhibition can be used to fill structures that have surfaces that may be damaged by plasma. For example, in 3D NAND structure, a gap is formed by two stacks each having multiple pairs of an oxide layer and a nitride layer. The stacks may be capped by a polysilicon layer such that the polysilicon layer forms the sidewalls of a vertically-oriented feature to be filled. Plasma inhibition processes can damage the polysilicon layer. Thermal inhibition processes as described herein may be used for damage-free inside-out and bottom-up gap fill.

As described above, the thermal inhibition involves exposure to a halogen-containing gas. Examples of fluorine-containing gases include NF₃, HF, fluorine (F₂), carbon tetrafluoride (CF₄), hexafluoroethane (C₂F₆), sulfur hexafluoride (SF₆), and chlorine trifluoride (ClF₃), sulfur tetrafluoride (SF₄), boron trifluoride (BF₃), silicon tetrafluoride (SiF₄), and difluorosilane (SiH₂F₄). Examples of chlorine-containing gases include hydrogen chloride (HCl), carbon tetrachloride (CCl₄), thionyl chloride (SOCl₂), chlorine (Cl₂), boron trifluoride (BCl₃), and silicon tetrafluoride (SiCl₄). Examples of bromine-containing gases include bromine (Br₂) and hydrogen bromide (HBr). Examples of iodine-containing gases include iodine (I₂) and hydrogen iodide (HI).

Depending on the halogen-containing gas, one or more additional gases may be provided to facilitate formation of a halogen-terminated surface. For example, H₂O may be provided to react with a fluorine-containing gas to form HF, which may then form an F-terminated surface. In some embodiments, a halogen-containing gas is provided with gases that form water, such as H₂ and O₂. Other H- and/or O-containing compounds may be used such as H₂O₂. In some embodiments, a halogen-containing gas is provided with an organic solvent (e.g., an alcohol) in addition to or instead of water.

Examples of alcohols include methanol, ethanol, 1-propanol, 2-propanol, 1-butanol, 2-butanol, t-butanol, 1-pentanol, 1-hexanol, 1-heptanol, 1-octanol, 1-nonanol, 1-decanol, and combinations thereof. In these or other cases, the organic solvent and/or water may include a laboratory solvent. Examples of laboratory solvents include acetonitrile, dichloromethane, carbon tetrachloride, and combinations thereof. In these or other cases, the organic solvent and/or water may include a ketone. Examples of ketones include acetone, acetophenone, and combinations thereof. In these or other implementations, the organic solvent and/or water may include an alkane. In some embodiments, the alkane may include an alkane selected from the group consisting of pentane, hexane, octane, cyclopentane, cyclohexane, and combinations thereof. In these or other embodiments, the organic solvent and/or water may include an aromatic solvent. In some cases, the aromatic solvent is an aromatic solvent such as toluene and/or benzene. In these or other implementations, the organic solvent and/or water may include an ether. In some such cases, the ether may include tetrahydrofuran. In these or other implementations, the organic solvent and/or water may include a nitrile. In some cases, the nitrile includes acetonitrile. In these or other implementations the organic solvent may include a carboxylic acid. In some cases, the carboxylic acid may include a carboxylic acid such as formic acid, acetic acid, propionic acid, butyric acid, valeric acid, caproic acid, enanthic acid, and caprylic acid.

In certain embodiments, a halogen-containing gas may be provided without additional gases or only with an inert gas. Examples include halosilanes. These may also be provided with an additional gas.

The inhibition operation may be diffusion-limited with the depth of inhibition controlled by one or more parameters such as inhibitor flow rate, inhibitor dilution, exposure time, and pressure. Referring to FIG. 1, for example, in some embodiments, the inhibition operation is performed such that a portion of each laterally-oriented feature 114 closest to the vertically-oriented hole 108 is inhibited, while portion deeper within the laterally-oriented feature 114 is not inhibited or inhibited to a less extent. And, as discussed above, the extent of inhibition of each laterally-oriented feature is the same from top-to-bottom.

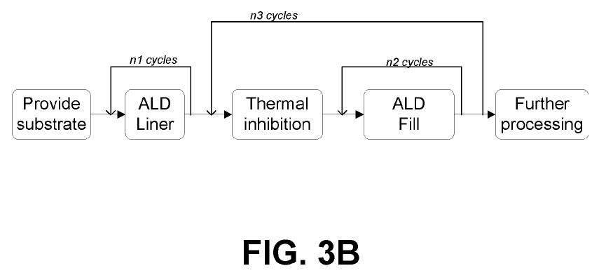

According to various embodiments, the thermal inhibition processes described herein involve a self-limiting etch of previously deposited material. FIG. 4 shows thickness for a thermal inhibition treatment at different pressures of blanket SiO₂ films deposited by ALD. The upper line represents a 6 Torr pressure and the lower line a 17.5 Torr pressure.

For both pressures, the thickness plateaus after about 20-40 seconds. This indicates that the etch is self-limiting. Thus, while pressure or other parameters may be used to ensure that the inhibition species reach the appropriate portions of the structure, the etch and degree of inhibition of those portions is relatively insensitive to those parameters.

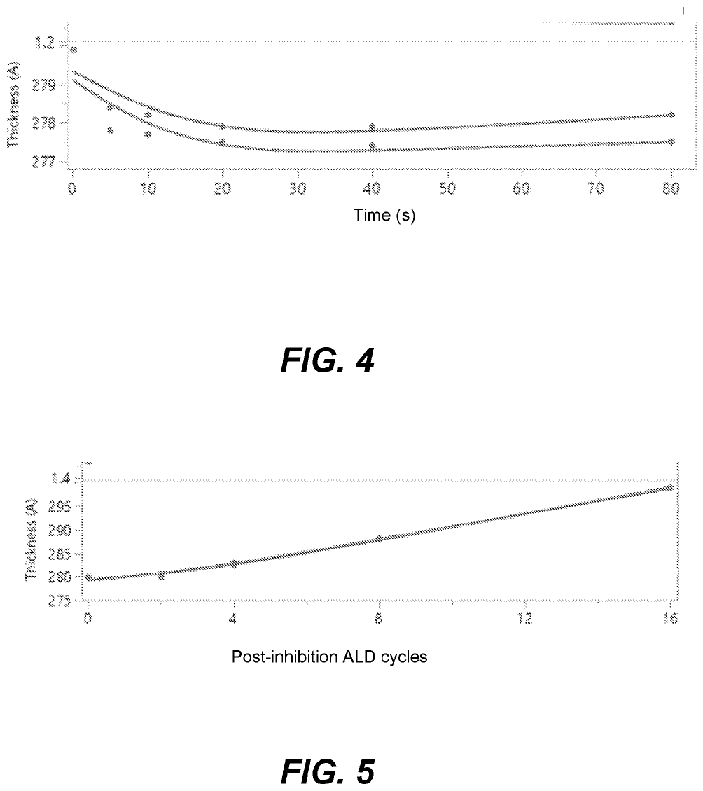

FIG. 5 shows thickness of subsequent ALD deposition as a function of number of ALD cycles after thermal inhibition at 6 Torr and 17.5 Torr on blanket SiO₂ films. No pressure dependence is shown, with the lines completely overlapping. In this example, the inhibition duration lasts for 2-3 cycles. Pressure may affect within feature inhibition degree.

Subsequently film may grow with a slower growth rate even while the inhibition effect is still present. This is because the inhibition treatment may not terminate every surface site that the precursor can absorb onto.

Examples of chamber pressure include 0.2 to 760 Torr, for example, 1 to 100 Torr, or 1 to 30 Torr. In some embodiments, a low pressure (e.g., 0.2 Torr to 10 Torr) may be used. Examples of substrate temperatures include 200° C. to 950° C., for example, 200° C. to 800° C., or 200° C. to 750° C.

If mixed with other reactants and/or an inert carrier gas, the halogen-containing gas may be fairly dilute. In an example, 0.1-1 slm (standard liters per minute) of NF3, 5 slm of H2, and 5 slm O₂ may be used.

Another aspect of the disclosure relates to filling features using a plasma-based inhibition process. FIG. 6 is a process flow diagram that illustrates a method of filling gaps with dielectric material. The method begins with providing a structure with one or more gaps to be filled. (601). The structure may be formed by one or more layers of material deposited on a substrate. The substrate may be a silicon or other semiconductor wafer, e.g., a 200-mm wafer, a 300-mm wafer, or a 450-mm wafer, including wafers having one or more layers of material, such as dielectric, conducting, or semi-conducting material deposited thereon. The methods may also be applied to for gap fill other substrates, such as glass, plastic, and the like, including in the fabrication of microelectromechanical (MEMS) devices.

Examples of structures include VDRAM structures, 3D NAND structures, and shallow trench isolation (STI) structures. The structures include gaps with the sidewalls of the gaps formed by a material susceptible to etch. In some embodiments, structures may include lateral structures that extend horizontally from a common vertical trench. Examples of sidewall materials include nitrides, oxides, metals, and semiconducting materials. The methods described herein are not limited to a particular class of sidewall material and may be used to inhibit any susceptible material.

Dielectric material is deposited in the gaps using an inhibition plasma (605). As discussed further below, this can involve cycles of atomic layer deposition (ALD) of the dielectric film followed by an inhibition plasma. According to various embodiments, exposure to the inhibition plasma may be at high pressure and/or have high radical density.

To generate plasmas having high radical density, an inductively coupled plasma (ICP) generator or remote plasma generator may be used.

In some embodiments, high pressure inhibition plasma is used. High pressure refers to the pressure of the process chamber during the inhibition plasma treatment. In some embodiments, a high-pressure plasma may be generated in-situ in the process chamber using a capacitively coupled plasma (CCP) generator.

The use of high pressure and/or high radical density plasmas can provide good top-to-bottom uniformity for lateral gap fill structures such as those shown in FIG. 1. In addition, in some embodiments, halogen-free inhibition species may be used. As further discussed below, halogen-free inhibition species have various advantages, including preventing halogen incorporation into a film. However, they may be less effective at inhibition. The use of high pressure can increase the effective of the inhibition plasmas, particularly for halogen-free inhibition species.

FIG. 7 shows an example of a process sequence that may be used in accordance with the disclosed embodiments. In the example process sequence of FIG. 7, a substrate such as a semiconductor wafer is provided for gap fill. It may be provided to a deposition chamber having undergone previous processing and/or be maintained in a deposition chamber. At this stage, the substrate includes one or more features to be filled with dielectric material. For example, a structure having laterally-oriented features as shown in FIG. 1 may be provided.

Then, n1 cycles of ALD deposition are performed, with n1 being an integer of at least 1. As described above, an ALD cycle may include the following operations: (i) delivery/adsorption of a precursor, (ii) purging of the precursor from the chamber, (iii) delivery of a second reactant and (iv) purging of byproducts from the chamber. The reaction between the second reactant and the adsorbed precursor to form a film on the surface of a substrate affects the film composition and properties, such as nonuniformity, stress, wet etch rate, dry etch rate, electrical properties (e.g., breakdown voltage and leakage current), etc. In a plasma-enhanced ALD (PEALD) process, a plasma may be ignited during or after the delivery of the second reactant in (iii). In the methods described with reference to FIG. 7, PEALD or thermal ALD may be used.

In the example of FIG. 7, the n1 cycles are sufficient to deposit a thin liner layer within the one or more features to be filled with dielectric material. The layer is generally conformal to the structure.

The n1 cycles of ALD may be thermal ALD or PEALD cycles. Further, the method may be used with other sources of activation such as exposure to UV light.

As indicated above, in some embodiments, a silicon-containing film is deposited by ALD. Examples of silicon-containing reactants that may be used in the ALD methods are provided further below. The methods may also be used to form other dielectric films including oxides such as gallium oxide, vanadium dioxide, hafnium oxide, zinc oxide, zirconium oxide, aluminum oxide, lithium (II) oxide, beryllium oxide, boron (III) oxide, magnesium oxide, titanium (III) oxide, iron (III) oxide, cobalt (II) oxide, and germanium (IV) oxide and nitrides such as gallium nitride, aluminum nitride, lithium nitride, and boron nitride Metals such as molybdenum, iron, cobalt, and germanium, and compounds such as SiGe may be formed using these techniques. Example of reactants that may be used for these certain films are described below.

The second reactant may vary depending on the film to be deposited. Silicon and other oxides may be deposited, for example, using oxygen (O₂) as second reactant. Other second reactants may be used including other oxidants to deposit oxides, nitrogen-containing reactants to deposit nitrides, carbon-containing reactants to deposit carbides, etc. Examples include O₂ and/or nitrous oxide (N₂O) to form a silicon oxide layer or silicon oxynitride layer, nitrogen (N₂) or ammonia (NH₃) to form a silicon nitride layer, methane (CH₄) to generate a silicon carbide layer etc. Appropriate mixtures of reactants may be used to form oxycarbides, oxycarbonitrides, oxynitrides, carbonitrides, etc.

After the n1 cycles are of ALD are performed to deposit a liner film, a plasma inhibition process is performed.

In some embodiments, the plasma inhibition process involves exposing the liner film to a plasma including halogen plasma species, such as, the plasma may include halogen species including anion and radical species such as F-, Cl-, I-, Br-, fluorine radicals, etc. In some embodiments, the plasma is generated from halogen containing gases. Examples of fluorine-containing gases include NF₃, HF, fluorine (F₂), carbon tetrafluoride (CF₄), hexafluoroethane (C₂F₆), sulfur hexafluoride (SF₆), and chlorine trifluoride (ClF₃), sulfur tetrafluoride (SF₄), boron trifluoride (BF₃), silicon tetrafluoride (SiF₄), and difluorosilane (SiH₂F₄). Examples of chlorine-containing gases include hydrogen chloride (HCl), carbon tetrachloride (CCl₄), thionyl chloride (SOCl₂), chlorine (Cl₂), boron trifluoride (BCl₃), and silicon tetrafluoride (SiCl₄). Examples of bromine-containing gases include bromine (Br₂) and hydrogen bromide (HBr). Examples of iodine-containing gases include iodine (I₂) and hydrogen iodide (HI). In some embodiments, the inhibition results in a surface that is at least partially halogen terminated.

Halogen-containing plasmas can be effective inhibition plasmas. For example, for some applications, a plasma generated from nitrogen trifluoride (NF₃) may provide an inhibition effect in a substantially reduced time compared to a plasma generated from molecular nitrogen (N₂).

In some embodiments, however, halogen-free inhibition plasmas are used. This can prevent halogen incorporation in the dielectric material. In addition to preventing incorporation of halogens into a film, a nitrogen-containing, halogen-free inhibition plasma such as a N₂ plasma can improve film properties by densifying the film. Another example of a nitrogen-containing, halogen-free plasma is one generated from ammonia (NH₃). In some embodiments, nitrogen-containing, halogen-free inhibition species may include plasma species generated from amines, with examples including methylamine, dimethylamine, and trimethylamine. In some embodiments, halogen-free species may include plasma species generated from hydrazine (N₂H₄). In some embodiments, a nitrogen-containing compound may be provided with hydrogen (H₂). For example, N₂ and H₂ mixtures may be used. An N₂:H₂ flow ratio can be 1:1 to 75:1, e.g., 1:1, 10:1, 20:1, 50:1, and 75:1

An inhibition plasma treatment may result in over-inhibition or under-inhibition, such that deposition does not sufficiently occur or results in voids, respectively. In some embodiments the inhibition plasma treatment may be performed at high pressure. High pressure refers to the pressure of the process chamber during the inhibition plasma treatment. High pressure may increase the effectiveness of the inhibition plasma, particularly for less effective inhibitors such as halogen-free inhibition species, including halogen-free, nitrogen-containing species such as N2. In some embodiments, a halogen-containing inhibition plasma is at high pressure to facilitate top-to-bottom uniformity for lateral gap fill.

At high pressure, the duration of an inhibition plasma treatment may be significantly reduced without reducing the inhibition depth or even increasing the inhibition depth when compared to a low pressure inhibition plasma treatment. In some embodiments, a high-pressure inhibition plasma treatment refers to a pressure of more than about 1 Torr, at least about 2 Torr, at least about 3 Torr, at least about 5 Torr, at least about 10 Torr, at least about 15 Torr, at least about 20 Torr, between about 10 Torr and about 30 Torr, or between about 15 Torr and 30 Torr.

In some embodiments, the plasma may have a high radical density. For example, it may have more radical species than ion species.

Returning to FIG. 7, after the plasma inhibition process is performed, n2 ALD cycles are performed to deposit dielectric material, including in the one or more features on the substrate to be filled. The reactants and deposited film in the ALD fill may be the same or different than used and formed in the ALD liner operation. The number of cycles, n2, is an integer of at least 1 and may be at least 2, or at least 3. In many embodiments, n2 is one with an inhibition plasma performed for every ALD cycle. The number of cycles may depend on structure geometry. Fewer cycles (and thus more inhibition and suppression of growth rate) may be used for structures that are more challenging to fill due to re-entrancy, narrow openings, and/or high aspect ratios. The plasma inhibition and n2 ALD cycles may be repeated for n3 total cycles, with n3 an integer of at least one. (If any of n1, n2, or n3 is one, the cycle under consideration is not repeated).

A sequence of inhibition followed by ALD may be referred to an as inhibition-deposition cycle. In some embodiments, the number n3 of total inhibition-deposition cycles is sufficient to complete fill of one or more features. In some embodiments, a n2 of 2, 3, or 4 may be used. According to various embodiments, the number n2 may be constant throughout the process or may vary. For example, at the beginning of the fill process, the inhibition may be more frequent. As the features beginning from the bottom up or inside out, the fill may become less challenging, allowing less frequent inhibition.

After the n3 cycles of inhibition-deposition are completed, further processing may be performed. This can include further ALD, PEALD, chemical vapor deposition (CVD), or plasma enhanced chemical vapor deposition (PECVD) of dielectric material, planarization, etching, etc.

In addition to laterally-oriented features as in the example of FIG. 1, the plasma inhibition may be used with other features in which plasma inhibition is challenging. These include high aspect ratio features including vertically-oriented features having aspect ratios of 10:1 or greater.

According to various embodiments, the chamber pressure during ALD and inhibition plasma may be the same or different. In some embodiments, the inhibition plasma is at relatively low power, e.g., at or less than 2000 W across 4 stations (500 W per station for a 300 mm wafer in a station). In some embodiments, it may be at or less than 1500 W across 4 stations (375 per station for a 300 mm wafer in a station). Higher plasma powers do not tend to significantly increase the inhibition effect.

Plasma power during a PEALD operation may be the same or different. Lowering plasma power during PEALD can result in better inhibition but adversely affect film properties. In some embodiments, plasma power during PEALD may range from 3000 to 5000 W across 4 stations (750 W to 1250 W per station for a 300 mm wafer in a station). In one example, PEALD power for a 300 mm wafer in a station is 1250 W followed by a 312.5 W inhibition treatment on the wafer. In these and other embodiments, the plasma power is lower for the inhibition plasma than PEALD.

Duration of inhibition is a strong factor in the extent of inhibition. According to various embodiments, the duration of each inhibition operation may be relatively long, e.g., from 5 to 300 seconds. The duration may depend on the structure, with deeper structures using longer durations. In some embodiments, the duration may be 5 to 20 seconds.

Chamber pressure may be constant throughout the process, including for ALD and inhibition plasma when performed in the same chamber. Example pressures range from 5 to 20 Torr. For PEALD and inhibition plasma, the chamber pressure may be below 10 Torr, e.g. 6 Torr. For thermal ALD and inhibition plasma, the chamber pressure may vary, e.g., 1 Torr to above 15 Torr.

Examples of substrate temperatures are 500° C. to 700° C., e.g., 550° C. to 650° C. The inhibition effect increases with increasing temperature during the inhibition plasma. Substantially lower temperatures (e.g., 50° C.) may also be used for inhibition. Increased temperatures may be used for improved film properties as the thermal budget allows in some embodiments.

In some embodiments, a process sequence as show in FIGS. 6 and 7 may be used in conjunction with a process sequence as shown in FIGS. 3A and 3B, such that one or more inhibition operations are thermal inhibition operations and one or more inhibition operations are plasma-based. The thermal and plasma-based inhibitions may be performed in any order. In some embodiments, for example, one or more cycles including a thermal inhibition may be used for deposition on a sensitive underlying layer that could be subject to damage if exposed to a plasma. After a certain thickness of film is deposited on the underlying layer, one or more cycles including a plasma-based inhibition may be used.

### Atomic Layer Deposition

FIG. 8 presents a process flow diagram for a single ALD cycle that may be implemented as part of any of the ALD operations shown in FIGS. 3B or 7 in which a silicon-containing film is formed. In an operation 802, the substrate is exposed to a silicon-containing precursor, to adsorb the precursor onto the surface of the feature. This operation may be self-limiting. In some embodiments, the precursor adsorbs to less than all the active sites on the surface of the feature. In an operation 804, the process chamber is optionally purged to remove any unadsorbed silicon-containing precursors. In an operation 806, the substrate is exposed to a co-reactant. Examples include O₂ and/or N₂O to form a silicon oxide layer or silicon oxynitride layer, N₂ or NH₃ to form a silicon nitride layer, methane (CH4) to generate a silicon carbide layer etc. For PEALD, the co-reactant may be plasma species generated from a gas such as O₂.

In operation 808, the process chamber is optionally purged to remove byproducts from the reaction between the silicon-containing precursor and the oxidant. Operations 802 through 808 repeated for a number of cycles to deposit the silicon-containing layer to a desired thickness in the feature.

It should be noted that the processes described herein are not limited to a particular reaction mechanism. Thus, a PEALD process described with respect to FIG. 8 includes all deposition processes that use sequential exposures to silicon-containing reactants and conversion plasmas, including those that are not strictly self-limiting. The process includes sequences in which one or more gases used to generate a plasma is continuously flowed throughout the process with intermittent plasma ignitions. For thermal inhibition, the process includes sequences in which one reactant (e.g., an oxidizing reactant) is flowed continuously while the other reactant is pulsed.

Further, while the description herein chiefly refers to temporal ALD in which the substrate remains stationary in a particular environment, such as a chamber or workstation, the methods may also be performed using spatial ALD. In spatial ALD, a substrate is moved to a different environment. Thus, in accordance with various embodiments, transitioning from operation 802 to operation 806 can include changing the susceptor temperature of the chamber or workstation, chamber pressure, gas flow rate, etc., and/or moving the substrate to another chamber or workstation having different process parameters.

In certain embodiments in which PEALD is performed, the plasma is an in-situ plasma, such that the plasma is formed directly above the substrate surface in the station. Example power per substrate areas for an in-situ plasma for PEALD are between about 0.2122 W/cm2 and about 2.122 W/cm2 in some embodiments. For example, the power may range from about 1000 W to about 6000 W for a chamber processing four 300 mm wafers. In some embodiments, the power may be between about 2500 W and about 6000 W for four 300 mm wafers. Plasmas for ALD processes may be generated by applying a radio frequency (RF) field to a gas using two capacitively coupled plates. Ionization of the gas between plates by the RF field ignites the plasma, creating free electrons in the plasma discharge region. These electrons are accelerated by the RF field and may collide with gas phase reactant molecules. Collision of these electrons with reactant molecules may form radical species that participate in the deposition process. It will be appreciated that the RF field may be coupled via any suitable electrodes. Non-limiting examples of electrodes include process gas distribution showerheads and substrate support pedestals. It will be appreciated that plasmas for ALD processes may be formed by one or more suitable methods other than capacitive coupling of an RF field to a gas. In some embodiments, the plasma is a remote plasma, such that second reactant is ignited in a remote plasma generator upstream of the station, then delivered to the station where the substrate is housed.

### ALD Reactants

For depositing silicon-containing films, one or more silicon-containing precursors may be used. Silicon-containing precursors suitable for use in accordance with disclosed embodiments include polysilanes (H3Si-(SiH2) n-SiH3), where n>0. Examples of silanes are silane (SiH4), disilane (Si2H6), and organosilanes such as methylsilane, ethylsilane, isopropylsilane, t-butylsilane, dimethylsilane, diethylsilane, di-t-butylsilane, allylsilane, sec-butylsilane, thexylsilane, isoamylsilane, t-butyldisilane, di-t-butyldisilane, and the like.

A halosilane includes at least one halogen group and may or may not include hydrogens and/or carbon groups. Examples of halosilanes are iodosilanes, bromosilanes, chlorosilanes, and fluorosilanes. Specific chlorosilanes are tetrachlorosilane, trichlorosilane, dichlorosilane, monochlorosilane, chloroallylsilane, chloromethylsilane, dichloromethylsilane, chlorodimethylsilane, chloroethylsilane, t-butylchlorosilane, di-t-butylchlorosilane, chloroisopropylsilane, chloro-sec-butylsilane, t-butyldimethylchlorosilane, thexyldimethylchlorosilane, and the like.

An aminosilane includes at least one nitrogen atom bonded to a silicon atom, but may also contain hydrogens, oxygens, halogens, and carbons. Examples of aminosilanes are mono-, di-, tri- and tetra-aminosilane (H3Si(NH₂), H₂Si(NH₂)₂, HSi(NH₂)3 and Si(NH₂)4, respectively), as well as substituted mono-, di-, tri- and tetra-aminosilanes, for example, t-butylaminosilane, methylaminosilane, tert-butylsilanamine, bis(tert-butylamino)silane (SiH₂(NHC(CH3)3)₂ (BTBAS), tert-butyl silylcarbamate, SiH(CH3)-(N(CH3)₂)₂, SiHCl-(N(CH3)₂)₂, (Si(CH3)₂NH)3, di-isopropylaminosilane (DIPAS), di-sec-butylaminosilane (DSBAS), SiH₂[N(CH₂CH3)₂]₂ (BDEAS) and the like. A further example of an aminosilane is trisilylamine (N(SiH3)). In some embodiments, an aminosilane that has two or more amine groups attached to the central Si atom may be used. These may result in less damage than aminosilanes having only a single amine group attached.

Further examples of silicon-containing precursors include trimethylsilane (3MS); ethylsilane; butasilanes; pentasilanes; octasilanes; heptasilane; hexasilane; cyclobutasilane; cycloheptasilane; cyclohexasilane; cyclooctasilane; cyclopentasilane; 1,4-dioxa-2,3,5,6-tetrasilacyclohexane; diethoxymethylsilane (DEMS); diethoxysilane (DES); dimethoxymethylsilane; dimethoxysilane (DMOS); methyl-diethoxysilane (MDES); methyl-dimethoxysilane (MDMS); octamethoxydodecasiloxane (OMODDS); tert-butoxydisilane; tetramethylcyclotetrasiloxane (TMCTS); tetraoxymethylcyclotetrasiloxane (TOMCTS); triethoxysilane (TES); triethoxysiloxane (TRIES); and trimethoxysilane (TMS or TriMOS).

In some implementations silicon-containing precursors may include siloxanes or amino-group-containing siloxanes. In some embodiments, siloxanes used herein may have a formula of X (R¹)ₐSi—O—Si(R²)_{b}Y, where a and b are integers from 0 to 2, and X and Y independently can be H or NR³R⁴, where each of R1, R2, R3 and R4 is hydrogen, unbranched alkyl, branched alkyl, saturated heterocyclic, unsaturated heterocyclic groups, or combinations thereof. In some embodiments, when at least one X or Y is NR³R⁴, R3 and R4, taken together with the atom to which each are attached, form a saturated heterocyclic compound. In some embodiments, the silicon-containing precursors are pentamethylated amino group containing siloxanes or dimethylated amino group containing siloxanes. Examples of amino group containing siloxanes include: 1-diethylamino 1,1,3,3,3,-pentamethyl disiloxane, 1-diisopropylamino-1,1,3,3,3,-pentamethyl disiloxane, 1 dipropylamino-1,1,3,3,3,-pentamethyl disiloxane, 1-di-n-butylamino-1,1,3,3,3,-pentamethyl disiloxane, 1-di-sec-butylamino-1,1,3,3,3,-pentamethyl disiloxane, 1-N-methylethylamino 1,1,3,3,3,-pentamethyl disiloxane, 1-N-methylpropylamino-1,1,3,3,3,-pentamethyl disiloxane, 1 N-methylbutylamino-1,1,3,3,3,-pentamethyl disiloxane, 1-t-butylamino-1,1,3,3,3,-pentamethyl disiloxane, 1-piperidino-1,1,3,3,3,-pentamethyl disiloxane, 1-dimethylamino-1,1-dimethyl disiloxane, 1-diethylamino-1, 1-dimethyl disiloxane, 1-diisopropylamino-1,1-dimethyl disiloxane, 1-dipropylamino-1,1-dimethyl disiloxane, 1-di-n-butylamino-1,1-dimethyl disiloxane, 1-di-sec butylamino-1,1-dimethyl disiloxane, 1-N-methylethylamino-1,1-dimethyl disiloxane, 1-N methylpropylamino-1,1-dimethyl disiloxan,e 1-N-methylbutylamino-1,1-dimethyl disiloxane, 1 piperidino-1,1-dimethyl disiloxane, 1-t-butylamino-1,1-dimethyl disiloxane, 1-dimethylamino-disiloxane, 1-diethylamino-disiloxane, 1-diisopropylamino-disiloxane, 1-dipropylamino-disiloxane, 1-di-n-butylamino-disiloxane, 1-di-sec-butylamino-disiloxane, 1-N methylethylamino-disiloxane, 1-N-methylpropylamino-disiloxane, 1-N-methylbutylamino-disiloxane, 1-piperidino-disiloxane, 1-t-butylamino disiloxane, and 1-dimethylamino-1,1,5,5,5,-pentamethyl disiloxane.

Examples of zirconium-containing precursors include bis(cyclopentadienyl)zirconium(IV) dihydride, bis(methyl-η5-cyclopentadienyl)methoxymethylzirconium, Dimethylbis(pentamethylcyclopentadienyl)zirconium(IV), tetrakis(diethylamido)zirconium(IV), tetrakis(dimethylamido)zirconium(IV), tetrakis(ethylmethylamido)zirconium(IV), zirconium(IV) dibutoxide(bis-2,4-pentanedionate), zirconium(IV) 2-ethylhexanoate, and zirconium tetrakis(2,2,6,6-tetramethyl-3,5-heptanedionate).

Examples of hafnium-containing precursors include bis(tert-butylcyclopentadienyl)dimethylhafnium(IV), bis(methyl-η5-cyclopentadienyl)dimethylhafnium, bis(methyl-η5-cyclopentadienyl)methoxymethylhafnium, bis(trimethylsilyl)amidohafnium(IV) chloride, dimethylbis(cyclopentadienyl)hafnium(IV), hafnium(IV)tert-butoxide, hafnium isopropoxide isopropanol adduct, tetrakis(diethylamido)hafnium(IV), tetrakis(dimethylamido)hafnium(IV), and tetrakis(ethylmethylamido)hafnium (IV),

Examples of vanadium-containing precursors include bis(cyclopentadienyl)vanadium(II) and vanadium(V) oxytriisopropoxide. An example niobium-containing precursor is bis(cyclopentadienyl)niobium(IV) dichloride. Examples of tantalum-containing precursors include pentakis(dimethylamino)tantalum(V), tantalum(V) ethoxide, tris(diethylamido)(tert-butylimido)tantalum(V), and tris(ethylmethylamido)(tert-butylimido)tantalum(V).

Example of gallium precursors include trimethylgallium and triethylgallium. Examples of aluminum precursors include trimethylaluminum and aluminum chloride. Examples of zinc precursors include zinc acetate, dimethyl zinc, and diethyl zinc.

Where a deposited film includes oxygen, an oxygen-containing reactant may be used. Examples of oxygen-containing reactants include, but are not limited to, oxygen (O₂), ozone (O₃), nitrous oxide (N₂O), nitric oxide (NO), nitrogen dioxide (NO₂), dinitrogen trioxide (N₂O₃), dinitrogen tetroxide (N₂O₄), dinitrogen pentoxide (N₂O₅), carbon monoxide (CO), carbon dioxide (CO₂), sulfur oxide (SO), sulfur dioxide (SO₂), oxygen-containing hydrocarbons (CₓH_{y}O_{z}), water (H₂O), formaldehyde (CH₂O), carbonyl sulfide (COS), mixtures thereof, etc.

Where a deposited film includes nitrogen, a nitrogen-containing reactant may be used. A nitrogen-containing reactant contains at least one nitrogen, for example, nitrogen (N₂), ammonia (NH₃), hydrazine (N₂H₄), amines (e.g., amines bearing carbon) such as methylamine (CH₅N), dimethylamine ((CH₃)₂NH), ethylamine (C₂H₅NH₂), isopropylamine (C₃H₉N), t-butylamine (C₄H₁₁N), di-t-butylamine (C₈H₁₉N), cyclopropylamine (C₃H₅NH₂), sec-butylamine (C₄H₁₁N), cyclobutylamine (C₄H₇NH₂), isoamylamine (C₅H₁₃N), 2-methylbutan-2-amine (C₅H₁₃N), trimethylamine (C₃H₉N), diisopropylamine (C₆H₁₅N), diethylisopropylamine (C₇H₁₇N), di-t-butylhydrazine (C₈H₂₀N₂), as well as aromatic containing amines such as anilines, pyridines, and benzylamines. Amines may be primary, secondary, tertiary or quaternary (for example, tetraalkylammonium compounds). A nitrogen-containing reactant can contain heteroatoms other than nitrogen, for example, hydroxylamine, t-butyloxycarbonyl amine and N-t-butyl hydroxylamine are nitrogen-containing reactants. Other examples include NₓO_{y} compounds such as nitrous oxide (N₂O), nitric oxide (NO), nitrogen dioxide (NO₂), dinitrogen trioxide (N₂O₃), dinitrogen tetroxide (N₂O₄) and/or dinitrogen pentoxide (N₂O₅).

### Apparatus

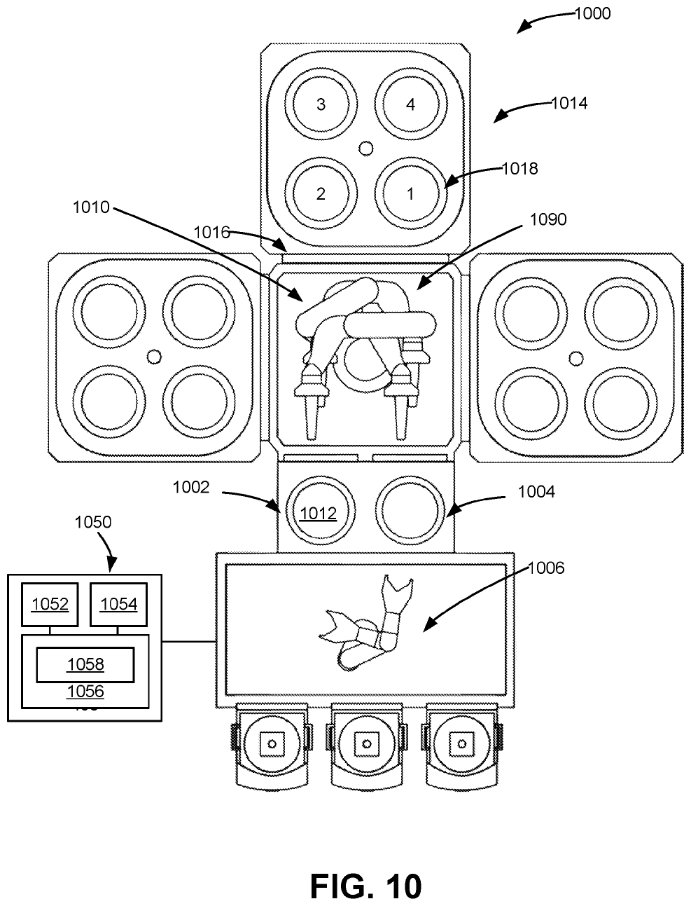

FIG. 9 depicts a schematic illustration of an embodiment of an atomic layer deposition (ALD) process station 900 having a process chamber body 902 for maintaining a low-pressure environment. A plurality of ALD process stations 900 may be included in a common low-pressure process tool environment. For example, FIG. 10 depicts an embodiment of a multi-station processing tool 700. In some embodiments, one or more hardware parameters of ALD process station 900, including those discussed in detail below, may be adjusted programmatically by one or more system controllers 950.

ALD process station 900 fluidly communicates with reactant delivery system 901a for delivering process gases to a distribution showerhead 906. Reactant delivery system 901a includes a mixing vessel 604 for blending and/or conditioning process gases for delivery to showerhead 606. In some embodiments, an inhibitor gas may be introduced to the mixing vessel prior to introduction to the chamber body 902, such as if provided with a carrier gas. In some embodiments, an inhibitor or other gas may be directly delivered to the chamber body 902. One or more mixing vessel inlet valves 920 may control introduction of process gases to mixing vessel 904. These valves may be controlled depending on whether a process gas, inhibitor gas, or carrier gas may be turned on during various operations. In some embodiments, an inhibitor gas may be generated by using an inhibitor liquid and vaporizing using a heated vaporizer.

As an example, the embodiment of FIG. 9 includes a vaporization point 903 for vaporizing liquid reactant to be supplied to the mixing vessel 904. In some embodiments, vaporization point 903 may be a heated vaporizer. The saturated reactant vapor produced from such vaporizers may condense in downstream delivery piping. Exposure of incompatible gases to the condensed reactant may create small particles. These small particles may clog piping, impede valve operation, contaminate substrates, etc. Some approaches to addressing these issues involve purging and/or evacuating the delivery piping to remove residual reactant. However, purging the delivery piping may increase process station cycle time, degrading process station throughput. Thus, in some embodiments, delivery piping downstream of vaporization point 903 may be heat traced. In some examples, mixing vessel 904 may also be heat traced. In one non-limiting example, piping downstream of vaporization point 903 has an increasing temperature profile extending from approximately 100° C. to approximately 150° C. at mixing vessel 904.

In some embodiments, liquid precursor or liquid reactant, such as a silicon-containing precursor, may be vaporized at a liquid injector. For example, a liquid injector may inject pulses of a liquid reactant into a carrier gas stream upstream of the mixing vessel. In one embodiment, a liquid injector may vaporize the reactant by flashing the liquid from a higher pressure to a lower pressure. In another example, a liquid injector may atomize the liquid into dispersed microdroplets that are subsequently vaporized in a heated delivery pipe. Smaller droplets may vaporize faster than larger droplets, reducing a delay between liquid injection and complete vaporization. Faster vaporization may reduce a length of piping downstream from vaporization point 603. In one scenario, a liquid injector may be mounted directly to mixing vessel 604. In another scenario, a liquid injector may be mounted directly to showerhead 606.

In some embodiments, a liquid flow controller (LFC) (not shown) upstream of vaporization point 9603 may be provided for controlling a mass flow of liquid for vaporization and delivery to process station 900. For example, the LFC may include a thermal mass flow meter (MFM) located downstream of the LFC. A plunger valve of the LFC may then be adjusted responsive to feedback control signals provided by a proportional-integral-derivative (PID) controller in electrical communication with the MFM. However, it may take one second or more to stabilize liquid flow using feedback control. This may extend a time for dosing a liquid reactant. Thus, in some embodiments, the LFC may be dynamically switched between a feedback control mode and a direct control mode. In some embodiments, this may be performed by disabling a sense tube of the LFC and the PID controller.

Showerhead 906 distributes gases toward substrate 912. For example, showerhead 906 may distribute an inhibitor gas to the substrate 912, silicon-containing precursor gas to the substrate 912, or a purge or carrier gas to the chamber body 902, a second reactant to the substrate 912, or a passivation gas to the substrate 912, in various operations. In the embodiment shown in FIG. 9, the substrate 912 is located beneath showerhead 606 and is shown resting on a pedestal 908. Showerhead 906 may have any suitable shape and may have any suitable number and arrangement of ports for distributing process gases to substrate 912.

In some embodiments, a microvolume is located beneath showerhead 606. Practicing disclosed embodiments in a microvolume rather than in the entire volume of a process station may reduce reactant exposure and purge times, may reduce times for altering process conditions (e.g., pressure, temperature, etc.) may limit an exposure of process station robotics to process gases, etc. Example microvolume sizes include, but are not limited to, volumes between 0.1 liter and 2 liters. This also impacts productivity throughput. In some embodiments, the disclosed embodiments are not performed in a microvolume.

In some embodiments, pedestal 908 may be raised or lowered to expose substrate 912 to microvolume 907 and/or to vary a volume of microvolume 907. For example, in a substrate transfer phase, pedestal 908 may be raised to position substrate 912 within microvolume 907. In some embodiments, microvolume 907 may completely enclose substrate 912 as well as a portion of pedestal 908 to create a region of high flow impedance.

Optionally, pedestal 908 may be lowered and/or raised during portions the process to modulate process pressure, reactant concentration, etc., within microvolume 907. In one scenario where process chamber body 902 remains at a base pressure during the process, lowering pedestal 908 may allow microvolume 907 to be evacuated. Example ratios of microvolume to process chamber volume include, but are not limited to, volume ratios between 1:500 and 1:10. It will be appreciated that, in some embodiments, pedestal height may be adjusted programmatically by a suitable computer controller 950.

In another scenario, adjusting a height of pedestal 608 may allow a plasma density to be varied during optional plasma activation processes. For example, the plasma may be activated when the inhibitor gas is introduced to the chamber body 902, or when the second reactant is flowed to the chamber body 902. In some embodiments, a plasma may not be activated during flow of the inhibitor gas or the flow of the second reactant. At the conclusion of the process phase, pedestal 908 may be lowered during another substrate transfer phase to allow removal of substrate 912 from pedestal 908.

While the example microvolume variations described herein refer to a height-adjustable pedestal 908, it will be appreciated that, in some embodiments, a position of showerhead 906 may be adjusted relative to pedestal 908 to vary a volume of microvolume 907. Further, it will be appreciated that a vertical position of pedestal 908 and/or showerhead 906 may be varied by any suitable mechanism within the scope of the present disclosure. In some embodiments, pedestal 908 may include a rotational axis for rotating an orientation of substrate 912. It will be appreciated that, in some embodiments, one or more of these example adjustments may be performed programmatically by one or more suitable controllers 950.

If a plasma is employed (e.g., for PEALD), showerhead 906 and pedestal 908 electrically communicate with a radio frequency (RF) power supply 914 and matching network 916 for powering a plasma. In some embodiments, the plasma energy may be controlled by controlling one or more of a process station pressure, gas concentrations and partial pressures of gases or gas flow rates, an RF source power, an RF source frequency, and a plasma power pulse timing. For example, RF power supply 914 and matching network 916 may be operated at any suitable power to form a plasma having a desired composition of radical species. Examples of suitable powers are included above. Likewise, RF power supply 914 may provide RF power of any suitable frequency. In some embodiments, RF power supply 914 may be configured to control high-and low-frequency RF power sources independently of one another. Example low-frequency RF frequencies may include, but are not limited to, frequencies between 0 kHz and 500 kHz. Example high-frequency RF frequencies may include, but are not limited to, frequencies between 1.8 MHz and 2.45 GHz, or greater than about 13.56 MHz, or greater than 27 MHz, or greater than 40 MHz, or greater than 60 MHz. It will be appreciated that any suitable parameters may be modulated discretely or continuously to provide plasma energy for the surface reactions. In one non-limiting example, the plasma power may be intermittently pulsed to reduce ion bombardment with the substrate surface relative to continuously powered plasmas.

In some embodiments, the plasma may be monitored in-situ by one or more plasma monitors. In one scenario, plasma power may be monitored by one or more voltage, current sensors (e.g., VI probes). In another scenario, plasma density and/or process gas concentration may be measured by one or more optical emission spectroscopy sensors (OES). In some embodiments, one or more plasma parameters may be programmatically adjusted based on measurements from such in-situ plasma monitors. For example, an OES sensor may be used in a feedback loop for providing programmatic control of plasma power. It will be appreciated that, in some embodiments, other monitors may be used to monitor the plasma and other process characteristics. Such monitors may include, but are not limited to, infrared (IR) monitors, acoustic monitors, and pressure transducers.

In some embodiments, instructions for a controller 950 may be provided via input/output control (IOC) sequencing instructions. In one example, the instructions for setting conditions for a process phase may be included in a corresponding recipe phase of a process recipe. In some cases, process recipe phases may be sequentially arranged, so that all instructions for a process phase are executed concurrently with that process phase. In some embodiments, instructions for setting one or more reactor parameters may be included in a recipe phase. For example, a first recipe phase may include instructions for setting a flow rate of an inert and/or a reactant gas (e.g., the first precursor such as a silicon-containing precursor), instructions for setting a flow rate of a carrier gas (such as argon), and time delay instructions for the first recipe phase. A second, subsequent recipe phase may include instructions for modulating or stopping a flow rate of an inert and/or a reactant gas, and instructions for modulating a flow rate of a carrier or purge gas and time delay instructions for the second recipe phase. A third recipe phase may include instructions for setting a flow rate of an inert, inhibitor and/or reactant gas which may be the same as or different from the gas used in the first recipe phase, instructions for modulating a flow rate of a carrier gas, and time delay instructions for the third recipe phase. A fourth recipe phase may include instructions for modulating or stopping a flow rate of an inert and/or a reactant gas (e.g., a second reactant such as nitrogen or a nitrogen-containing or oxygen-containing gas), instructions for modulating the flow rate of a carrier or purge gas, and time delay instructions for the fourth recipe phase. It will be appreciated that these recipe phases may be further subdivided and/or iterated in any suitable way within the scope of the present disclosure.

In some embodiments, pedestal 908 may be temperature controlled via heater 610. Further, in some embodiments, pressure control for process station 900 may be provided by butterfly valve 918. As shown in the embodiment of FIG. 9, butterfly valve 918 throttles a vacuum provided by a downstream vacuum pump (not shown). However, in some embodiments, pressure control of process station 900 may also be adjusted by varying a flow rate of one or more gases introduced to the process station 900.

As described above, one or more process stations may be included in a multi-station processing tool. FIG. 10 shows a schematic view of an embodiment of a multi-station processing tool 1000 with an inbound load lock 1002 and an outbound load lock 704, either or both of which may include a remote plasma source. A robot 1006, at atmospheric pressure, is configured to move wafers from a cassette into inbound load lock 1002. A wafer is placed by the robot 1006 on a pedestal 1012 in the inbound load lock 1002, the atmospheric port 1010 is closed, and the load lock is pumped down. Where the inbound load lock 1002 includes a remote plasma source, the wafer may be exposed to a remote plasma treatment in the load lock prior to being introduced into a processing chamber 1014. Further, the wafer also may be heated in the inbound load lock 1002 as well, for example, to remove moisture and adsorbed gases. Next, a chamber transport port 1016 to processing chamber 1014 is opened, and a robot places the wafer into the reactor on a pedestal of a first station shown in the reactor for processing. While the embodiment depicted in FIG. 10 includes load locks, it will be appreciated that, in some embodiments, direct entry of a wafer into a process station may be provided.

The depicted processing chamber 1014 includes four process stations, numbered from 1 to 4 in the embodiment shown in FIG. 10. Each station has a heated pedestal (shown at 1018 for station 1), and gas line inlets. It will be appreciated that in some embodiments, each process station may have different or multiple purposes. While the depicted processing chamber 1014 includes four stations, it will be understood that a processing chamber according to the present disclosure may have any suitable number of stations. For example, in some embodiments, a processing chamber may have five or more stations, while in other embodiments a processing chamber may have three or fewer stations.

Each station may perform the same or different operations as another station. In some embodiments, inhibition is performed only at one or a subset of stations.

FIG. 10 depicts an embodiment of a wafer handling system 1090 for transferring wafers. In some embodiments, wafer handling system 1090 may transfer wafers between various process stations and/or between a process station and a load lock. It will be appreciated that any suitable wafer handling system may be employed. Non-limiting examples include wafer carousels and wafer handling robots. FIG. 10 also depicts an embodiment of a system controller 1050 employed to control process conditions and hardware states of process tool 1000. System controller 1050 may include one or more memory devices 1056, one or more mass storage devices 1054, and one or more processors 1052. Processor 1052 may include a CPU or computer, analog and/or digital input/output connections, stepper motor controller boards, etc.

In some embodiments, system controller 1050 controls all the activities of process tool 1000. System controller 1050 executes system control software 1058 stored in mass storage device 1054, loaded into memory device 1056, and executed on processor 1052. Alternatively, the control logic may be hard coded in the controller 1050. Applications Specific Integrated Circuits, Programmable Logic Devices (e.g., field-programmable gate arrays, or FPGAs) and the like may be used for these purposes. In the following discussion, wherever “software” or “code” is used, functionally comparable hard coded logic may be used in its place. System control software 1058 may include instructions for controlling the timing, mixture of gases, gas flow rates, chamber and/or station pressure, chamber and/or station temperature, wafer temperature, target power levels, RF power levels, substrate pedestal, chuck and/or susceptor position, and other parameters of a particular process performed by process tool 1000. System control software 1058 may be configured in any suitable way. For example, various process tool component subroutines or control objects may be written to control operation of the process tool components used to carry out various process tool processes. System control software 1058 may be coded in any suitable computer readable programming language.

In some embodiments, system control software 1058 may include input/output control (IOC) sequencing instructions for controlling the various parameters described above. Other computer software and/or programs stored on mass storage device 1054 and/or memory device 856 associated with system controller 1050 may be employed in some embodiments. Examples of programs or sections of programs for this purpose include a substrate positioning program, a process gas control program, a pressure control program, a heater control program, and a plasma control program.

A substrate positioning program may include program code for process tool components that are used to load the substrate onto pedestal 1018 and to control the spacing between the substrate and other parts of process tool 1000.

A process gas control program may include code for controlling gas composition (e.g., silicon-containing precursor, co-reactant, inhibition, passivation, and purge gases as described herein) and flow rates and optionally for flowing gas into one or more process stations prior to deposition in order to stabilize the pressure in the process station. A pressure control program may include code for controlling the pressure in the process station by regulating, for example, a throttle valve in the exhaust system of the process station, a gas flow into the process station, etc.

A heater control program may include code for controlling the current to a heating unit that is used to heat the substrate. Alternatively, the heater control program may control delivery of a heat transfer gas (such as helium) to the substrate.

A plasma control program may include code for setting RF power levels applied to the process electrodes in one or more process stations in accordance with the embodiments herein.

A pressure control program may include code for maintaining the pressure in the reaction chamber in accordance with the embodiments herein.

In some embodiments, there may be a user interface associated with system controller 1050. The user interface may include a display screen, graphical software displays of the apparatus and/or process conditions, and user input devices such as pointing devices, keyboards, touch screens, microphones, etc.

In some embodiments, parameters adjusted by system controller 1050 may relate to process conditions. Non-limiting examples include process gas composition and flow rates, temperature, pressure, plasma conditions (such as RF bias power levels), etc. These parameters may be provided to the user in the form of a recipe, which may be entered utilizing the user interface.

Signals for monitoring the process may be provided by analog and/or digital input connections of system controller 1050 from various process tool sensors. The signals for controlling the process may be output on the analog and digital output connections of process tool 1000. Non-limiting examples of process tool sensors that may be monitored include mass flow controllers, pressure sensors (such as manometers), thermocouples, etc. Appropriately programmed feedback and control algorithms may be used with data from these sensors to maintain process conditions.

System controller 1050 may provide program instructions for implementing the above-described deposition processes. The program instructions may control a variety of process parameters, such as DC power level, RF bias power level, pressure, temperature, etc. The instructions may control the parameters to operate in-situ deposition of film stacks according to various embodiments described herein.

The system controller 1050 will typically include one or more memory devices and one or more processors configured to execute the instructions so that the apparatus will perform a method in accordance with disclosed embodiments. Machine-readable media containing instructions for controlling process operations in accordance with disclosed embodiments may be coupled to the system controller 1050.

In some implementations, the system controller 1050 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The system controller 750, depending on the processing conditions and/or the type of system, may be programmed to control any of the processes disclosed herein, including the delivery of processing gases and/or inhibitor gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the system controller 1050 may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the system controller 750 in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The system controller 1050, in some implementations, may be a part of or coupled to a computer that is integrated with, coupled to the system, otherwise networked to the system, or a combination thereof. For example, the system controller 1050 may be in the “cloud” or all or a part of a fab host computer system, which can allow for remote access of the wafer processing The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the system controller 750 receives instructions in the form of data, which specify parameters for each of the processing steps to be performed during one or more operations. The parameters may be specific to the type of process to be performed and the type of tool that the system controller 1050 is configured to interface with or control. Thus, as described above, the system controller 1050 may be distributed, such as by including one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an ALD chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the system controller 1050 might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

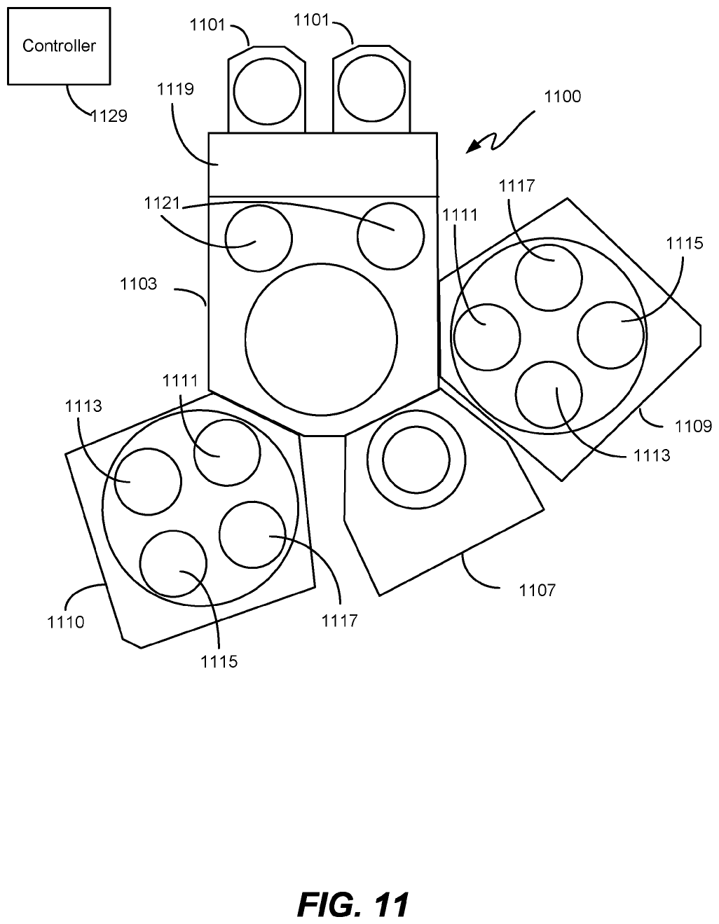

FIG. 11 is a block diagram of another processing system suitable for conducting deposition processes in accordance with certain embodiments. The system 1100 includes a transfer module 1103. Mounted on the transfer module 1103 are two multi-station reactors 1109 and 1110, each capable of performing inhibition treatments and/or ALD and/or CVD according to certain embodiments. Reactors 1109 and 1110 may include multiple stations 1111, 1113, 1115, and 1117 that may sequentially or non-sequentially perform operations in accordance with disclosed embodiments. The stations may include a heated pedestal or substrate support, one or more gas inlets or showerhead or dispersion plate.

Also mounted on the transfer module 1103 may be one or more single or multi-station modules 1107 capable of performing plasma or chemical (non-plasma) pre-cleans, or any other processes described in relation to the disclosed methods. The module 1107 may in some cases be used for various treatments to, for example, prepare a substrate for a deposition process. The module 1107 may also be designed/configured to perform various other processes such as etching or polishing. The system 1100 also includes one or more wafer source modules 1101, where wafers are stored before and after processing. An atmospheric robot (not shown) in the atmospheric transfer chamber 1119 may first remove wafers from the source modules 1101 to loadlocks 1121. A wafer transfer device (generally a robot arm unit) in the transfer module 1103 moves the wafers from loadlocks 1121 to and among the modules mounted on the transfer module 1103. In various embodiments, a system controller 1129 is employed to control process conditions during deposition as described above with respect to FIG. 10.

System control logic for system controllers described herein may be configured in any suitable way. In general, the logic can be designed or configured in hardware and/or software. The instructions for controlling the drive circuitry may be hard coded or provided as software. The instructions may be provided by “programming.” Such programming is understood to include logic of any form, including hard coded logic in digital signal processors, application-specific integrated circuits, and other devices which have specific algorithms implemented as hardware. Programming is also understood to include software or firmware instructions that may be executed on a general purpose processor. System control software may be coded in any suitable computer readable programming language.

The computer program code for controlling the germanium-containing reducing agent pulses, hydrogen flow, and tungsten-containing precursor pulses, and other processes in a process sequence can be written in any conventional computer readable programming language: for example, assembly language, C, C++, Pascal, Fortran, or others. Compiled object code or script is executed by the processor to perform the tasks identified in the program. Also as indicated, the program code may be hard coded.

The controller parameters relate to process conditions, such as, for example, process gas composition and flow rates, temperature, pressure, cooling gas pressure, substrate temperature, and chamber wall temperature. These parameters are provided to the user in the form of a recipe, and may be entered utilizing the user interface. Signals for monitoring the process may be provided by analog and/or digital input connections of the system controller 950 or 1050. The signals for controlling the process are output on the analog and digital output connections of the deposition apparatus.

The system software may be designed or configured in many different ways. For example, various chamber component subroutines or control objects may be written to control operation of the chamber components necessary to carry out the deposition processes (and other processes, in some cases) in accordance with the disclosed embodiments. Examples of programs or sections of programs for this purpose include substrate positioning code, process gas control code, pressure control code, and heater control code.

In some implementations, a controller, such as controller 950, 1050, or 1129 is part of a system, which may be part of the above-described examples. Such systems can include semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems. The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings in some systems, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process. In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control. Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

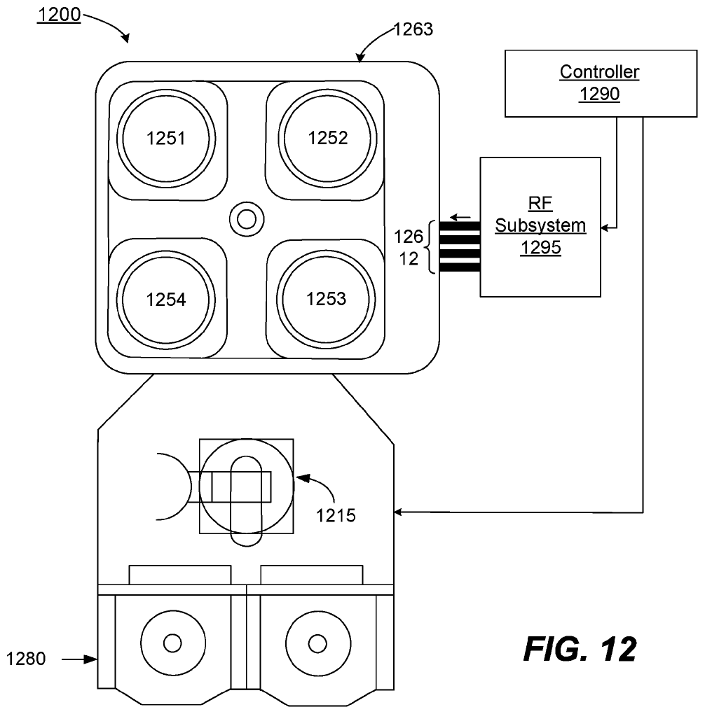

It may be appreciated that a plurality of process stations may be included in a multi-station processing tool environment, such as shown in FIG. 12, which depicts a schematic view of an embodiment of a multi-station processing tool. Processing apparatus 1200 employs an integrated circuit fabrication chamber 1263 that includes multiple fabrication process stations, each of which may be used to perform processing operations on a substrate held in a wafer holder, such as a pedestal, at a particular process station. In the embodiment of FIG. 12, the integrated circuit fabrication chamber 1263 is shown having four process stations 1251, 1252, 1253, and 1254. Other similar multi-station processing apparatuses may have more or fewer process stations depending on the implementation and, for example, a desired level of parallel wafer processing, size/space constraints, cost constraints, etc. Also shown in FIG. 12 is substrate handler robot 1275, which may operate under the control of system controller 1290, configured to move substrates from a wafer cassette (not shown in FIG. 12) from loading port 1280 and into integrated circuit fabrication chamber 1263, and onto one of process stations 1251, 1252, 1253, and 1254.

FIG. 12 also depicts an embodiment of a system controller 1290 employed to control process conditions and hardware states of processing apparatus 1200. System controller 1290 may include one or more memory devices, one or more mass storage devices, and one or more processors, as described herein.

RF subsystem 1295 may generate and convey RF power to integrated circuit fabrication chamber 1263 via radio frequency input ports 1267. In particular embodiments, integrated circuit fabrication chamber 1263 may comprise input ports in addition to radio frequency input ports 1267 (additional input ports not shown in FIG. 12). Accordingly, integrated circuit fabrication chamber 1263 may utilize 8 RF input ports. In particular embodiments, process stations 1251-1254 of integrated circuit fabrication chamber 1263 may each utilize first and second input ports in which a first input port may convey a signal having a first frequency and in which a second input port may convey a signal having a second frequency. Use of dual frequencies may bring about enhanced plasma characteristics.

According to various embodiments, the inhibition and deposition operations of each cycle may occur in the same or different chambers. In some embodiments, the inhibition operation and deposition operations are performed in a chamber with gas flows and RF powers appropriately controlled as described above for each operation. In a multi-station chamber, one or more stations may be used for deposition with one or more separate stations used for inhibition. Alternatively, each station may be for both operations.

The apparatus/process described herein may be used in conjunction with lithographic patterning tools or processes, for example, for the fabrication or manufacture of semiconductor devices, displays, LEDs, photovoltaic panels and the like. Typically, though not necessarily, such tools/processes will be used or conducted together in a common fabrication facility. Lithographic patterning of a film typically includes some or all of the following operations, each operation enabled with a number of possible tools: (1) application of photoresist on a workpiece, i.e., substrate, using a spin-on or spray-on tool; (2) curing of photoresist using a hot plate or furnace or UV curing tool; (3) exposing the photoresist to visible or UV or x-ray light with a tool such as a wafer stepper; (4) developing the resist so as to selectively remove resist and thereby pattern it using a tool such as a wet bench; (5) transferring the resist pattern into an underlying film or workpiece by using a dry or plasma-assisted etching tool; and (6) removing the resist using a tool such as an RF or microwave plasma resist stripper.

### CONCLUSION

Although the foregoing embodiments have been described in some detail for purposes of clarity of understanding, it will be apparent that certain changes and modifications may be practiced within the scope of the appended claims. It should be noted that there are many alternative ways of implementing the processes, systems, and apparatus of the present embodiments. Accordingly, the present embodiments are to be considered as illustrative and not restrictive, and the embodiments are not to be limited to the details given herein.

What is claimed is:

1. A method for filling a feature of a structure on a substrate in a chamber, the method comprising:
performing one or more cycles of:
(e) providing a halogen-containing gas to the chamber under non-plasma conditions to inhibit deposition on at least part of the feature;
(f) performing one or more atomic layer deposition cycles to deposit a dielectric material in the feature.

2. The method of claim 1, wherein the dielectric material is an oxide, a nitride, or a carbide.

3. The method of claim 1, further comprising, before performing one or more cycles of (a) and (b), depositing a liner layer in the feature by atomic layer deposition.

4. The method of claim 1, wherein (a) results in a self-limiting etch.

5. The method of claim 1, wherein (a) results in a halogen-terminated surface.

6. The method of claim 1, wherein (a) further comprises providing water or one or more reactants that can form water to the chamber.

7. The method of claim 1, wherein (b) comprises providing a halogen-containing gas, hydrogen (H₂), and oxygen (O₂) to the chamber.

8. The method of claim 1, wherein the structure comprises a vertically-oriented feature, the vertically-oriented feature having sidewalls, a plurality of openings in the sidewalls leading to a plurality of laterally-oriented features fluidically accessible through the plurality of openings, and wherein the feature is one of the laterally-oriented features.

9. The method of claim 8, further comprising performing one or more cycles of:
(g) providing a halogen-containing gas or a halogen-free gas to the chamber under plasma conditions to inhibit deposition on at least part of the feature;
(h) performing one or more atomic layer deposition cycles to deposit a dielectric material in the feature.

10. A method for filling a feature of a structure on a substrate in a chamber, the method comprising:
performing one or more inhibition-deposition cycles of:
(c) providing a plasma generated from a nitrogen-containing halogen-free gas to the chamber to inhibit deposition on at least part of the feature, wherein the chamber pressure is at least 5 Torr during (a); and
(d) performing one or more atomic layer deposition cycles to deposit a dielectric material in the feature.
